(19) United States
(12) Patent Application Publication
(10) Pub. No.: US 2023/0081224 A1
(43) Pub. Date: Mar. 16, 2023

(54) METHOD AND SYSTEM FOR EVALUATING TEST DATA, WAFER TEST SYSTEM, AND STORAGE MEDIUM

(71) Applicant: CHANGXIN MEMORY TECHNOLOGIES, INC., Hefei City (CN)

(72) Inventor: Shisheng WANG, Hefei (CN)

(21) Appl. No.: 17/839,703

(22) Filed: Jun. 14, 2022

Related U.S. Application Data
(63) Continuation of application No. PCT/CN2021/131807, filed on Nov. 19, 2021.

(30) Foreign Application Priority Data
Sep. 10, 2021 (CN) 202111063641.8

(51) Int. Cl. G01R 31/28

(52) U.S. Cl. CPC G01R 31/2851

(57) ABSTRACT

A method and system for evaluating test data, a wafer test system, and a storage medium are provided. The method for evaluating test data includes: obtaining test data of a plurality of test programs, each test program including a plurality of test items; for each test program, calculating a correlation coefficient of each test item according to the test data; drawing a difference analysis graph for every two test programs in the plurality of test programs according to the correlation coefficient between each of the test items in different test programs, where a horizontal axis and a longitudinal axis of the difference analysis graph respectively correspond to one test program; and evaluating a difference of each test item in two different test programs according to the difference analysis graph.

### CROSS-REFERENCE TO RELATED APPLICATION

This application is a continuation application of International Patent Application No. PCT/CN2021/131807, filed on Nov. 19, 2021, which is filed based on Chinese Patent Application No. 202111063641.8, filed on Sep. 10, 2021, and entitled “METHOD AND SYSTEM FOR EVALUATING TEST DATA, WAFER TEST SYSTEM, AND STORAGE MEDIUM”, and claims priority to the Chinese patent application. International Patent Application No. PCT/CN2021/131807 and Chinese Patent Application No. 202111063641.8 are incorporated herein by reference in their entireties.

### BACKGROUND

After wafer production is completed, it is necessary to perform a circuit probing, and generate a large amount of wafer test data. In actual analysis, it is necessary to analyze a correlation of wafer test data obtained from different electrical tests, so as to find a correlation between different test items. In actual mass production, the amount of these data is huge, which includes thousands of test items, and each test item will have millions of data.

However, during the production process, a test program generally needs to be updated and optimized, so that when test data of a wafer is subjected to correlation detection, it is more difficult to detect an anomaly of a correlation between wafer test data caused by different test programs.

### SUMMARY

The disclosure relates to the technical field of semiconductors, and in particular, to a method and system for evaluating test data, a wafer test system, and a storage medium.

In this regard, embodiments of the disclosure provide a method and system for evaluating test data, a wafer test system, and a storage medium in order to solve at least one problem existing in the prior art.

In order to achieve the foregoing objective, the technical solutions of the embodiments of the disclosure are implemented as follows.

In a first aspect, the embodiments of the disclosure provide a method for evaluating test data. The method includes that:

test data of a plurality of test programs are obtained, each test program including a plurality of test items;

for each test program, a correlation coefficient of each test item is calculated according to the test data;

a difference analysis graph for every two test programs in the plurality of test programs is drawn according to the correlation coefficient between each of the test items in different test programs, where a horizontal axis and a longitudinal axis of the difference analysis graph respectively correspond to one test program; and

evaluating a difference of each test item in two different test programs according to the difference analysis graph.

In a second aspect, the embodiments of the disclosure provide a system for evaluating test data. The system includes a processor and a memory for storing executable instructions executed by the processor. The processor is configured to:

obtain test data of a plurality of test programs, each test program including a plurality of test items;

for each test program, calculate a correlation coefficient of each test item according to the test data;

draw a difference analysis graph for every two test programs in the plurality of test programs according to the correlation coefficient between each of the test items in different test programs, where a horizontal axis and a longitudinal axis of the difference analysis graph respectively correspond to one test program; and

evaluate a difference of each test item in two different test programs according to the difference analysis graph.

In a third aspect, the embodiments of the disclosure provide a computer-readable storage medium having stored therein a computer program that when executed by a processor, implements a method for evaluating the test data, and the method includes that:

test data of a plurality of test programs are obtained, each test program including a plurality of test items;

for each test program, a correlation coefficient of each test item is calculated according to the test data;

a difference analysis graph for every two test programs in the plurality of test programs is drawn according to the correlation coefficient between each of the test items in different test programs, where a horizontal axis and a longitudinal axis of the difference analysis graph respectively correspond to one test program; and

evaluating a difference of each test item in two different test programs according to the difference analysis graph.

### BRIEF DESCRIPTION OF THE DRAWINGS

In the drawings, identical reference numerals throughout the multiple drawings denote identical or similar parts or elements unless otherwise specified. The drawings are not necessarily drawn to scale. It should be understood that these drawings depict only some embodiments disclosed in accordance with the disclosure and are not to be considered as limiting the scope of the disclosure.

FIG. 1 is a schematic flowchart of a method for evaluating test data according to an embodiment of the disclosure;

FIG. 2 is an obtained test data table according to a particular implementation of the disclosure;

FIG. 3A is a box plot of D_VDLY_DQ_DC according to an embodiment of the disclosure;

FIG. 3B is a box plot of IFSB_DC according to an embodiment of the disclosure;

FIG. 3C is a box plot of M_DELAY_DC according to an embodiment of the disclosure;

FIG. 4 is a schematic diagram of a difference analysis graph according to an embodiment of the disclosure;

FIG. 5 is a data table corresponding to coordinate points having a significant difference in the difference analysis graph illustrated in FIG. 4;

FIG. 6A is a schematic diagram of a correlation between D_LBIAS_DQ_DC and D_VDLY_DQ_DC according to an embodiment of the disclosure;

FIG. 6B is a schematic diagram of a correlation between D_LBIAS_DQ_DC and IDD2P_DC according to an embodiment of the disclosure;

FIG. 6C is a schematic diagram of a correlation between D_LBIAS_DQ_DC and IDD3P_DC according to an embodiment of the disclosure;

FIG. 6D is a schematic diagram of a correlation between D_LBIAS_DQ_DC and IFSB_DC according to an embodiment of the disclosure; and

FIG. 7 is a schematic structural diagram of a system for evaluating test data according to an embodiment of the disclosure.

### DETAILED DESCRIPTION

In the following description, numerous specific details are given in order to provide a more thorough understanding of the disclosure. However, it will be apparent to persons skilled in the art that the disclosure may be implemented without one or more of these details. In other examples, in order to avoid confusion with the disclosure, some technical features well known in the art are not described. That is, all the features of the actual embodiments are not described herein, and well-known functions and structures are not described in detail.

In addition, the accompanying drawings are merely exemplary diagrams of the disclosure, and are not drawn to scale. The same reference numbers in the drawings represent the same or similar parts, and therefore, repeated descriptions thereof are omitted. Some of the block diagrams illustrated in the accompanying drawings are functional entities and do not necessarily correspond to physically or logically independent entities. Such functional entities may be implemented in the form of software, or implemented in one or more hardware modules or integrated circuits, or implemented in different networks and/or processor apparatuses and/or micro-controller apparatuses.

The flowcharts illustrated in the drawings are merely illustrative and not necessarily include all of the steps. For example, some steps can be decomposed, and some steps can be combined or partially merged, so the actual execution order can vary depending on the actual situation.

The terms used herein are for the purpose of describing particular embodiments only and is not intended to limit the disclosure. As used herein, the singular forms “a”, “an” and “the/said” are intended to include the plural forms as well, unless the context clearly indicates otherwise. It should be further understood that the terms “comprises” and/or “comprising”, when used in this description, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of the associated listed items.

In the manufacturing process of integrated circuits, a large amount of data such as electrical test data may be generated in real time. Moreover, it is necessary to analyze these data, and to analyze, in time, a correlation of wafer test data obtained from different electrical tests, so as to find out a correlation between different test items, to perform corresponding adjustment or optimization on the test items and the like, thereby ensuring that a produced product has high yield and reliability. However, in the production process, in addition to analyzing the correlation between different test items, the correlation between different test items caused by different test programs also needs to be analyzed. At present, these data are analyzed manually by engineers themselves. However, as the number of test programs and test items becomes larger and larger, existing manual analysis methods cannot comprehensively and quickly process these big data. Moreover, the inspection of the results is also time-consuming. The engineers spend a large amount of time on analysis of data that is not significantly correlated to key parameters modified in subsequent processes or electrical properties of a final device, and thus the determination for abnormal data is not sensitive enough, and abnormal data cannot be found quickly and accurately. Therefore, an abnormal condition of a test program and a test item cannot be found in time, which leads to the failure to corresponding adjust or optimize on the test program and the test item in time, resulting in a delay for improving the performance of a final device. It is apparent that the existing manual data analysis methods cannot meet analysis requirements of big data in manufacturing of the integrated circuits.

Therefore, the following implementations of the disclosure are provided.

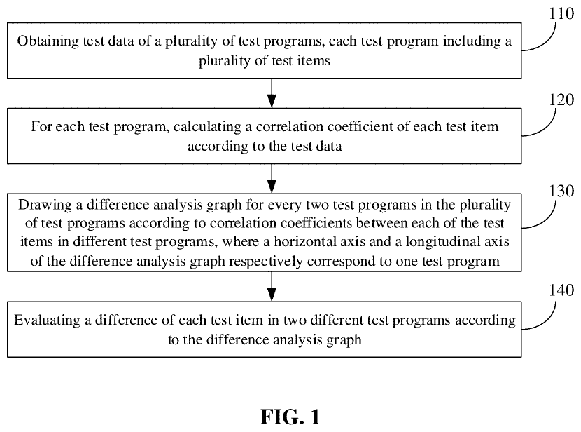

Embodiments of the disclosure provide a method for evaluating test data. FIG. 1 is a schematic flowchart of a method for evaluating test data according to an embodiment of the disclosure. As illustrated in FIG. 1, the method includes the following operations.

In operation 110, test data of a plurality of test programs are obtained, each test program including a plurality of test items.

In some embodiments, the test data is test data generated in a circuit probing stage. In some other embodiments, the test data may also be test data generated in other wafer test stages, and the other wafer tests include, for example, a wafer acceptance test, a fault test, a failure graphic analysis test, etc.

It should be noted that, the case that the test data is the test data generated in the circuit probing stage is taken as an example for description.

In the embodiments of the disclosure, operation 110 specifically includes that: a target product corresponding to the plurality of test programs is determined according to set parameters; and test data of a preset test category of the target product are obtained from a test database, where the preset test category include a plurality of test categories, and each test category corresponds to a plurality of test items. Here, the set parameters include a test program identifier (PROGRAM ID), a product identifier (PRODUCT ID), a wafer identifier (WAFER ID), a chip identifier (CHIP ID), and a process step identifier (STEP ID). In a specific implementation, for each test program, test data of 400 wafers is randomly fetched from a wafer level database according to a set test program identifier, product identifier and process step identifier, that is, each test program fetches test data of 400 wafers. It should be noted that the number of wafers fetched can be determined according to actual requirements.

In a specific implementation, for each test program, all test items of the three test categories of Data Collection (DC), Bit Failure Classification Region Count (FRC), and Redundance Data (RD) are continued to be fetched from the test data of the 400 wafers fetched. Here, the preset test category include the DC, the FRC, and the RD.

In operation 120, for each test program, a correlation coefficient of the each test item is calculated according to the test data.

In the embodiments of the disclosure, before the operation 120, the method for evaluating the test data further includes: merging the test data of the preset test category according to the set parameters to generate a merged data table.

In a specific implementation, the test data of the test items of the three test categories of the DC, the FRC, and the RD is merged into a data table through the wafer identifier, the chip identifier, and the test program. In the embodiments of the disclosure, during obtaining the test data, the test data is first merged according to the category of the test items, so that in the subsequent process, the test data can be analyzed and evaluated faster and more conveniently.

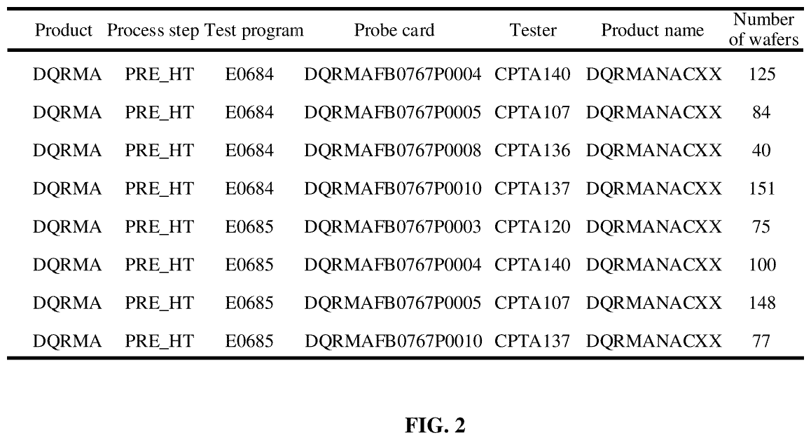

FIG. 2 is an obtained test data table according to a particular implementation of the disclosure. From the table illustrated in FIG. 2, for a product with the product name as DQRMANACXX and the product identifier as DQRMA, in the PRE_HT process step, test data of test programs E0684 and E0685 is fetched. For the test program E0684, test data of 125 wafers with the probe card identifier as DQRMAFB0767P0004 and the tester as CPTA140 is fetched, test data of 84 wafers with the probe card identifier as DQRMAFB0767P0005 and the tester as CPTA107 is fetched, test data of 40 wafers with the probe card identifier as DQRMAFB0767P0008 and the tester as CPTA136 is fetched, and test data of 151 wafers with the probe card identifier as DQRMAFB0767P0010 and the tester as CPTA137 is fetched, which are a total of test data of 400 wafers. For the test program E0685, test data of 75 wafers with the probe card identifier as DQRMAFB0767P0003 and the tester as CPTA120 is fetched, test data of 100 wafers with the probe card identifier as DQRMAFB0767P0004 and the tester as CPTA140 is fetched, test data of 148 wafers with the probe card identifier as DQRMAFB0767P0005 and the tester as CPTA107 is fetched, and test data of 77 wafers with the probe card identifier as DQRMAFB0767P0010 and the tester as CPTA137 is fetched, which are a total of test data of 400 wafers.

In the embodiments of the disclosure, before operation 120, the method for evaluating the test data further includes: drawing a box plot for each test item according to the test data of each test item in different test programs; and for each test item, removing abnormal test data by using the box plot. Abnormal test data that exceeds the lower bound (Q₁−1.5×IQR) and the upper bound (Q₃+1.5×IQR) is removed by the box plot. Q₁ is a lower quartile, Q₃ is an upper quartile, IQR is an interquartile range, and IQR=Q₃−Q₁.

Here, the case where the test data of two test programs are obtained is taken an example for description. The two test programs are E0684 and E0685, respectively. Each test program includes the same test items. In some embodiments, the test items included in each test program may be divided into three test categories, which are the DC, the FRC, and the RD, respectively. The DC includes the test items: D_LBIAS_DQ_DC, D_VDLY_DQ_DC, IDD2P_DC, IDD3P_DC, IFSB_DC, M_CMDDLY_DC, M_DELAY_DC, M_ODP_DC, M_OSC_DC, M_TAA_DC, PWR_SHORT_DC, VDDSHT1_DC, VDDSHT2_DC, VDDSHT4_DC, VDDSHTS_DC, etc. The RD includes the test items: p_RD, S_RD, z_RD, etc. The FRC includes the test items: LZ_BLS1_FRC, S_PAUSB_288_FRC, etc.

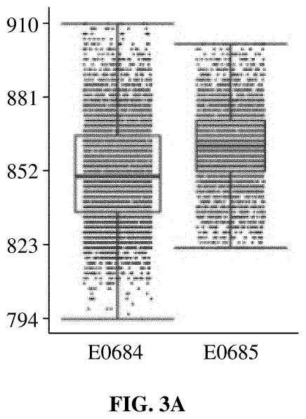

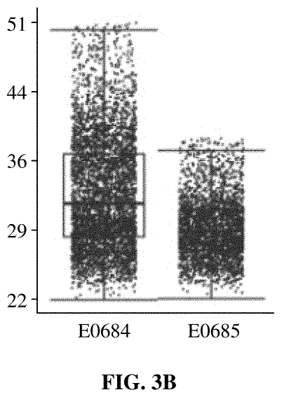

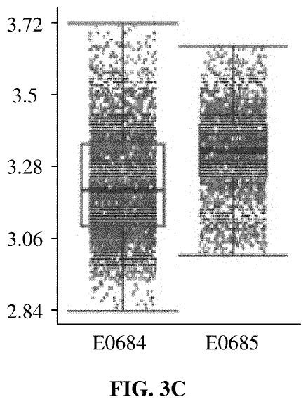

Here, the three test items D_VDLY_DQ_DC, IFSB_DC, and M_DELAY_DC are taken as an example for description. FIG. 3A is a box plot of D_VDLY_DQ_DC according to an embodiment of the disclosure. FIG. 3B is a box plot of IFSB_DC according to an embodiment of the disclosure. FIG. 3C is a box plot of M_DELAY_DC according to an embodiment of the disclosure. As illustrated in FIG. 3A to FIG. 3C, the abscissa of the box plot is different test programs, and the ordinate is test data.

In the embodiments of the disclosure, the difference of each test item in different test programs is evaluated by means of the box plot. As illustrated in FIG. 3A to FIG. 3C, according to the box plots corresponding to different test items, the difference of each test item in the two test programs E0684 and E0685 may be roughly evaluated.

In the embodiments of the disclosure, for each test item, in response that a median in one of the plurality of test programs is greater than an upper quartile in another test program or less than a lower quartile in another test program, it is evaluated that the test item has a significance difference in different test programs. As illustrated in FIG. 3A, the median of the test item D_VDLY_DQ_DC in the test program E0684 is 850, the upper quartile is 860, and the lower quartile is 835; and the median of the test item D_VDLY_DQ_DC in the test program E0685 is 865, the upper quartile is 875, and the lower quartile is 855. The median (850) of the test item D_VDLY_DQ_DC in the test program E0684 is less than the lower quartile (855) in the test program E0685, and the median (865) of the test item D_VDLY_DQ_DC in the test program E0685 is greater than the upper quartile (860) in the test program E0684. Therefore, it is evaluated that the test item D_VDLY_DQ_DC has a significant difference in the test programs E0684 and E0685.

As illustrated in FIG. 3B, the median of the test item IFSB_DC in the test program E0684 is 33, the upper quartile is 38, and the lower quartile is 29; and the median of the test item IFSB_DC in the test program E0685 is 29, the upper quartile is 33, and the lower quartile is 25. The median (33) of the test item IFSB_DC in the test program E0684 is not greater than the upper quartile (33) in the test program E0685, and the median (29) of the test item IFSB_DC in the test program E0685 is not less than the lower quartile (29) in the test program E0684. Therefore, it is evaluated that the test item IFSB_DC has no significant difference in the test programs E0684 and E0685.

As illustrated in FIG. 3C, the median of the test item M_DELAY_DC in the test program E0684 is 3.21, the upper quartile is 3.32, and the lower quartile is 3.11; and the median of the test item M_DELAY_DC in the test program E0685 is 3.3, the upper quartile is 3.4, and the lower quartile is 3.24. The median (3.21) of the test item M_DELAY_DC in the test program E0684 is less than the lower quartile (3.24) in the test program E0685, and the median (3.3) of the test item M_DELAY_DC in the test program E0685 is not greater than the upper quartile (3.32) in the test program E0684. Therefore, it is evaluated that the test item M_DELAY_DC has a significant difference in the test programs E0684 and E0685.

In the embodiments of the disclosure, a distribution condition of each test item in different test programs may be counted through the box plot of each test item, and whether each test item has a significance difference in different test programs is evaluated through the box plot.

In the embodiments of the disclosure, the specific process of operation 120 is that: the correlation coefficient between each of the test items is calculated according to the test data after removing the abnormal test data.

In the embodiments of the disclosure, the correlation coefficient between each of the test items is calculated by using a Pearson correlation coefficient calculation formula. A difference analysis graph is drawn for every two test programs in the plurality of test programs according to the Pearson correlation coefficient between each of the test items in different test programs, where a horizontal axis and a longitudinal axis of the difference analysis graph respectively correspond to one test program.

The Pearson correlation coefficient is used to measure a linear relationship between variables, and the calculation formula of the Pearson correlation coefficient is:

$${ρ}_{x , y} = \frac{cov ( x , y )}{{σ}_{x} {σ}_{y}} = \frac{E [ ( x - {μ}_{x} ) ( y - {μ}_{y} ) ]}{{σ}_{x} {σ}_{y}}$$

The Pearson correlation coefficient formula is defined as: the Pearson correlation coefficient ρ_{x, y} between the two variables (x, y) is equal to the covariance cox(x, y) of the two variables divided by the product σₓσ_{y} of their standard deviations.

In some embodiments, the calculated correlation coefficient includes any one of the Pearson correlation coefficient, a Spearman correlation coefficient, or a Kendall correlation coefficient. In other embodiments, the calculated correlation coefficient may also be other correlation coefficients in the art.

In operation 130, a difference analysis graph is drawn for every two test programs in the plurality of test programs according to the correlation coefficients between each of the test items in different test programs, where a horizontal axis and a longitudinal axis of the difference analysis graph respectively correspond to one test program.

In operation 140, a difference of each test item in two different test programs is evaluated according to the difference analysis graph.

In the embodiments of the disclosure, for a first quadrant and a third quadrant of the difference analysis graph, operation 140 includes: for every two test items in the plurality of test items, in response that a difference value between a correlation coefficient between the two test items in a test program and a correlation coefficient between the two test items in another test program is greater than a first preset value, evaluating that the two test items have a significant difference in two different test programs.

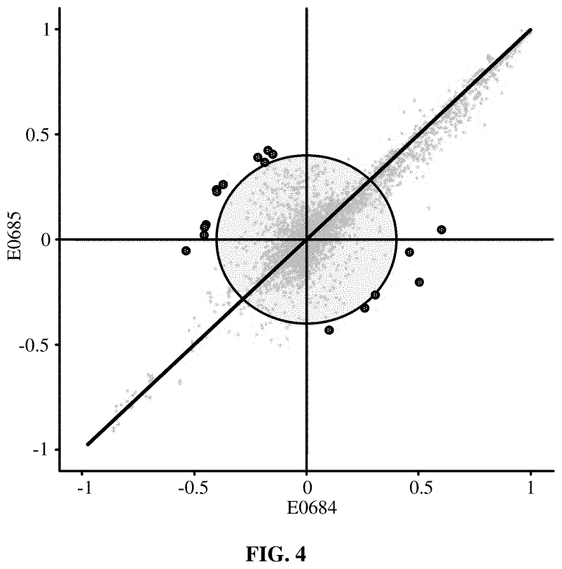

FIG. 4 is a schematic diagram of a difference analysis graph according to an embodiment of the disclosure. It should be noted that, in FIG. 4, description is made by taking test programs E0684 and E0685 as an example. In FIG. 4, the abscissa of the difference analysis graph is the test program E0684, and the ordinate is the test program E0685. In FIG. 4, coordinate points represented by hollow dots are coordinate points corresponding to two test items having a significant difference. As illustrated in FIG. 4, for the first quadrant and the third quadrant of the difference analysis graph, in response that a difference value between a correlation coefficient between the two test items in the test program E0684 and a correlation coefficient between the two test items in the test program E0685 is greater than 0.5, it is evaluated that the two test items have a significant difference in the test programs E0684 and E0685.

In the embodiments of the disclosure, for a second quadrant and a fourth quadrant of the difference analysis graph, operation 140 further includes that: in response that a distance from a coordinate point formed by a correlation coefficient between the two test items in a test program and a correlation coefficient between the two test items in another test program to an origin of the difference analysis graph is greater than a second preset value, it is evaluated that the two test items have a significant difference in two different test programs. As illustrated in FIG. 4, for the second quadrant and the fourth quadrant of the difference analysis graph, in response that a distance from a coordinate point formed by a correlation coefficient between the two test items in the test program E0684 and a correlation coefficient between the two test items in the test program E0685 to an origin of the difference analysis graph is greater than 0.4, it is evaluated that the two test items have a significant difference in the test programs E0684 and E0685.

Here, in actual application, the first preset value may be 0.5, the second preset value may be 0.4, and the first preset value is greater than the second preset value. Since the values of the correlation coefficients corresponding to the coordinate points of the first quadrant and the third quadrant have identical signs (either positive or negative), the test items corresponding to the coordinate points of the first quadrant and the third quadrant have a similar correlation in two different test programs. Therefore, the first preset value is set to be greater than the second preset value, for example, the first preset value is set to be greater than or equal to 0.5, in order for reflecting the large difference between two correlation coefficients by increasing the difference, thereby indicating that the corresponding test item has a significant difference in two different test programs. However, the values of the correlation coefficients corresponding to the coordinate points of the second quadrant and the fourth quadrant have different signs (one being positive and the other being negative), which indicates that the correlation between the test items corresponding to the coordinate points of the second quadrant and the fourth quadrant has a certain difference in two different test programs. Therefore, as long as the second preset value is greater than or equal to 0.4, it is sufficient to indicate that the corresponding test item has a significant difference in two different test programs.

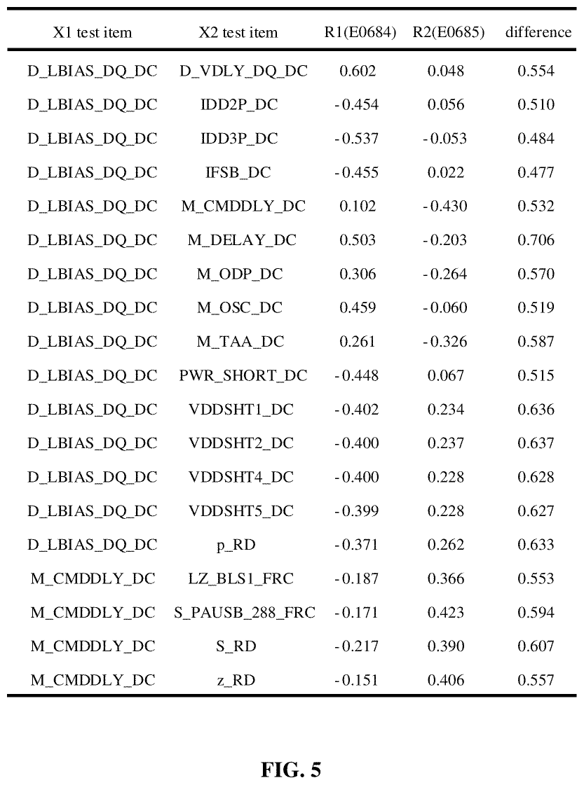

FIG. 5 is a data table corresponding to coordinate points having a significant difference in the difference analysis graph illustrated in FIG. 4. In FIG. 5, R1 represents a correlation coefficient between the X1 test item and the X2 test item in the test program E0684, R2 represents a correlation coefficient between the X1 test item and the X2 test item in the test program E0685, and difference represents a difference between R1 and R2. It can be seen from FIG. 5 that the coordinate points corresponding to the differences having a significant difference are all within the first quadrant and the third quadrant, that is, coordinate points with the difference between R1 and R2 being greater than 0.5, or are all within the second quadrant and the fourth quadrant, that is, coordinate points in which the distance from the coordinate point formed by R1 and R2 to the origin is greater than 0.4.

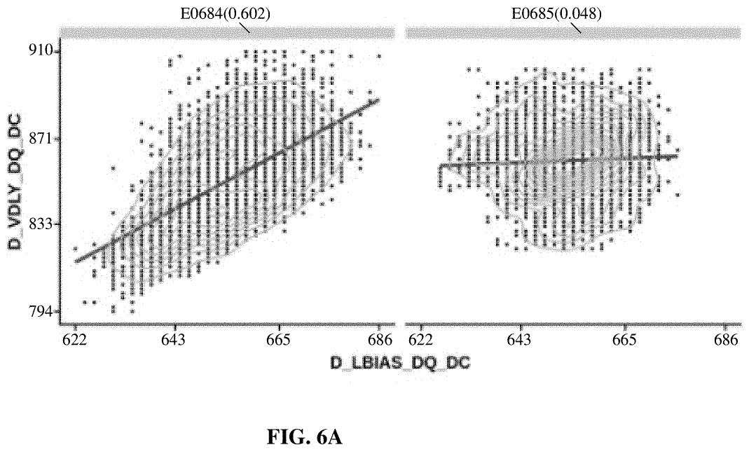

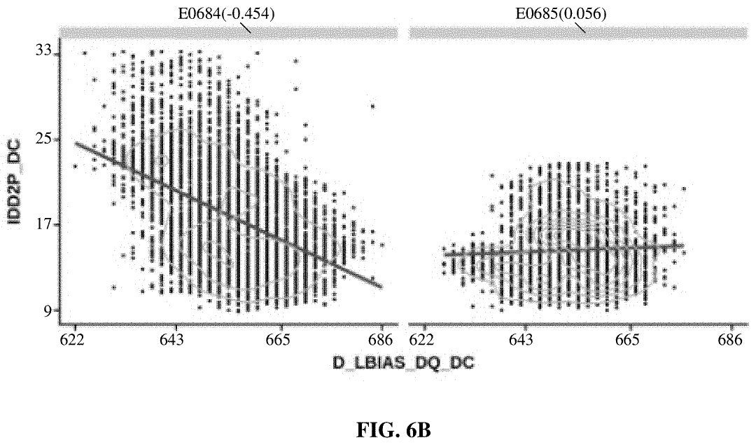

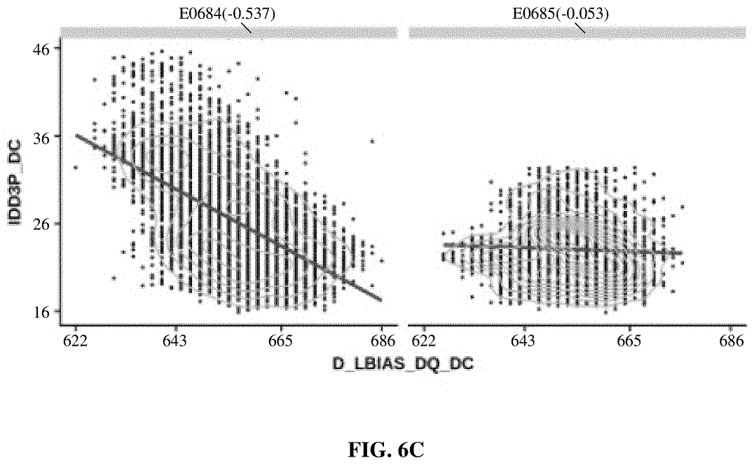

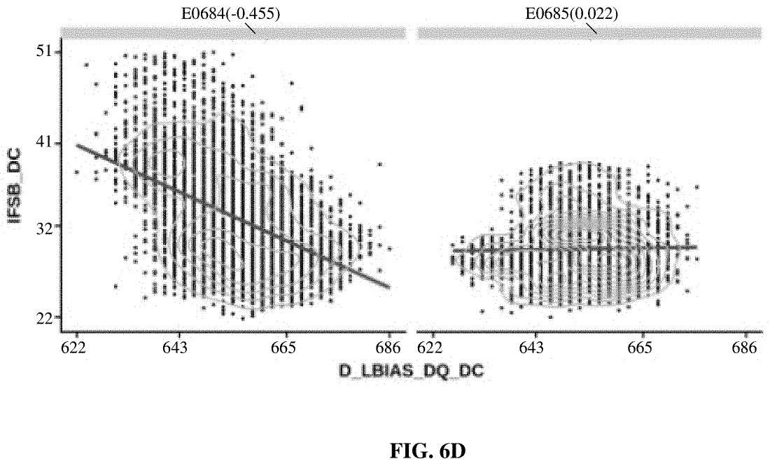

Here, the case where X1 is D_LBIAS_DQ_DC and X2 is D_VDLY_DQ_DC is taken as an example for description. FIG. 6A is a schematic diagram of a correlation between D_LBIAS_DQ_DC and D_VDLY_DQ_DC according to an embodiment of the disclosure. In FIG. 6A, the abscissa of the schematic diagram of the correlation is test data of D_LBIASDQ_DC, and the ordinate is test data of D_VDLY_DQ_DC. It should be noted that, in FIG. 6A, the correlation coefficient between D_LBIAS_DQ_DC and D_VDLY_DQ_DC in the test program E0684 is 0.602, and the correlation coefficient between D_LBIAS_DQ_DC and D_LBIAS_DQ_DC in the test program E0685 is 0.048. As illustrated in FIG. 6A, the test data distribution of the test items D_LBIAS_DQ_DC and D_VDLY_DQ_DC in the test programs E0684 and E0685 has a great difference. Therefore, it can be evaluated that the test items D_LBIAS_DQ_DC and D_VDLY_DQ_DC have a significant difference in the test programs E0684 and E0685.

Here, the case where X1 is D_LBIAS_DQ_DC and X2 is IDD2P_DC is taken as an example for description. FIG. 6B is a schematic diagram of a correlation between D_LBIAS_DQ_DC and IDD2P_DC according to an embodiment of the disclosure. In FIG. 6B, the abscissa of the schematic diagram of the correlation is test data of D_LBIAS_DQ_DC, and the ordinate is test data of IDD2P_DC. It should be noted that, in FIG. 6B, the correlation coefficient between D_LBIAS_DQ_DC and IDD2P_DC in the test program E0684 is −0.454, and the correlation coefficient between D_LBIAS_DQ_DC and IDD2P_DC in the test program E0685 is 0.056. As illustrated in FIG. 6B, the test data distribution of the test items D_LBIAS_DQ_DC and IDD2P_DC in the test programs E0684 and E0685 has a great difference. Therefore, it can be evaluated that the test items D_LBIAS_DQ_DC and IDD2P_DC have a significant difference in the test programs E0684 and E0685.

Here, the case where X1 is D_LBIAS_DQ_DC and X2 is IDD3P_DC is taken as an example for description. FIG. 6C is a schematic diagram of a correlation between D_LBIAS_DQ_DC and IDD3P_DC according to an embodiment of the disclosure. In FIG. 6C, the abscissa of the schematic diagram of the correlation is test data of D_LBIAS_DQ_DC, and the ordinate is test data of IDD3P_DC. It should be noted that, in FIG. 6C, the correlation coefficient between D_LBIAS_DQ_DC and IDD3P_DC in the test program E0684 is −0.573, and the correlation coefficient between D_LBIAS_DQ_DC and IDD3P_DC in the test program E0685 is −0.053. As illustrated in FIG. 6C, the test data distribution of the test items D_LBIAS_DQ_DC and IDD3P_DC in the test programs E0684 and E0685 has a great difference. Therefore, it can be evaluated that the test items D_LBIAS_DQ_DC and IDD3P_DC have a significant difference in the test programs E0684 and E0685.

Here, the case where X1 is D_LBIAS_DQ_DC and X2 is IFSB_DC is taken as an example for description. FIG. 6D is a schematic diagram of a correlation between D_LBIAS_DQ_DC and IFSB_DC according to an embodiment of the disclosure. In FIG. 6D, the abscissa of the schematic diagram of the correlation is test data of D_LBIAS_DQ_DC, and the ordinate is test data of IFSB_DC. It should be noted that, in FIG. 6D, the correlation coefficient between D_LBIAS_DQ_DC and IFSB_DC in the test program E0684 is −0.455, and the correlation coefficient between D_LBIAS_DQ_DC and IFSB_DC in the test program E0685 is 0.022. As illustrated in FIG. 6D, the test data distribution of the test items D_LBIAS_DQ_DC and IFSB_DC in the test programs E0684 and E0685 has a great difference. Therefore, it can be evaluated that the test items D_LBIAS_DQ_DC and IFSB_DC have a significant difference in the test programs E0684 and E0685.

Thus, a difference analysis graph is drawn for every two test programs in the plurality of test programs according to the correlation coefficients between each of the test items in different test programs, and a difference of each test item in two different test programs is evaluated according to the difference analysis graph. An anomaly of a correlation difference between each of the test items caused by different test programs may be obtained according to the difference evaluation, so that the engineer can perform corresponding adjustment or optimization on the test program or the test item in time on the basis of the anomaly difference, thereby improving performance of a final device.

In the embodiments of the disclosure, after the operation 140, the method for evaluating the test data further includes that: a difference report is generated according to the evaluated difference of each test item in the two different test programs; and the difference report is periodically uploaded. In a specific implementation, periodically uploading the difference report may be periodically sending the difference report to the engineer via E-mail.

In the technical solutions provided in the disclosure, the test data is automatically extracted from the database through the set parameters, and the test data of the preset test category are merged to facilitate subsequent data analysis; then, the box plot is drawn for each test item through a statistical method, and the difference of each test item in different test programs is evaluated through the box plot, so as to find out the test items having a significant difference in different test programs; the difference analysis graph is drawn for every two test programs in the plurality of test programs according to the correlation coefficient between each of the test items in different test programs; and the difference of each test item in two different test programs is evaluated on the basis of the difference analysis graph, so as to find out a test item pair having a significant difference in different test programs. Then, the generated difference report is automatically mailed to the engineer periodically, so that the engineer can find out the problem and solve the problem in time through the difference report.

Through the method for evaluating the test data provided in the disclosure, difference evaluation of each test item in different test programs is realized. It is also can assist the engineer to determine whether an abnormal change in the correlation between each of the test items is related to different test programs. An anomaly of a correlation difference between each of the test items caused by different test programs may be obtained according to the difference of each test item in different test programs, so that the engineer can perform corresponding adjustment or optimization on the test program or the test item in time on the basis of the anomaly difference, thereby improving performance of a final device.

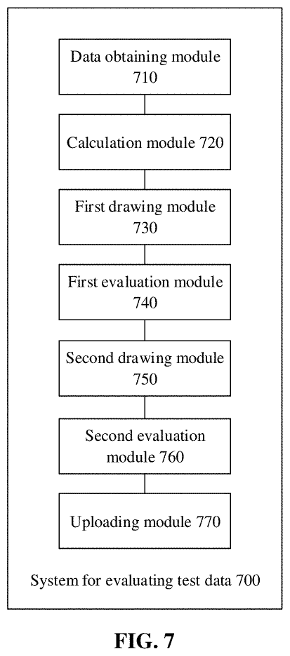

On the basis of the technical concept which is the same as that of the method for evaluating the test data, the embodiments of the disclosure provide a system for evaluating test data. FIG. 7 is a schematic structural diagram of a system for evaluating test data according to an embodiment of the disclosure. As illustrated in FIG. 7, the 700 for evaluating the test data includes a data obtaining module 710, a calculation module 720, a first drawing module 730, and a first evaluation module 740.

The data obtaining module 710 is configured to obtain test data of a plurality of test programs, each test program including a plurality of test items.

The calculation module 720 is configured to, for each test program, calculate a correlation coefficient of each the test item according to the test data.

The first drawing module 730 is configured to draw a difference analysis graph for every two test programs in the plurality of test programs according to the correlation coefficient between each of the test items in different test programs, where a horizontal axis and a longitudinal axis of the difference analysis graph respectively correspond to one test program.

The first evaluation module 740 is configured to evaluate a difference of each test item in two different test programs according to the difference analysis graph.

In some embodiments, the system for evaluating the test data 700 further includes: a second drawing module 750, configured to: draw a box plot for each test item according to the test data of each test item in different test programs; and for each test item, remove abnormal test data by using the box plot.

In some embodiments, the calculation module 720 is specifically configured to calculate correlation coefficient between each of the test items according to test data after removing the abnormal test data.

In some embodiments, each test program includes the same test items.

In some embodiments, the system 700 for evaluating the test data further includes: a second evaluation module 760, configured to evaluate the difference of each test item in different test programs based on the box plot.

In some embodiments, the second evaluation module 760 is specifically configured to: for each test item, in response that a median in one of the plurality of test programs is greater than an upper quartile in another test program or less than a lower quartile in another test program, evaluate that the test item has a significance difference in different test programs.

In some embodiments, the calculation module 720 is specifically configured to calculate the correlation coefficient between each of the test items by using a Pearson correlation coefficient calculation formula.

In some embodiments, for a first quadrant and a third quadrant of the difference analysis graph, the first evaluation module 740 is specifically configured to: for every two test items in the plurality of test items, in response that a difference value between a correlation coefficient between the two test items in a test program and a correlation coefficient between the two test items in another test program is greater than a first preset value, evaluate that the two test items have a significant difference in two different test programs.

In some embodiments, for a second quadrant and a fourth quadrant of the difference analysis graph, the first evaluation module 740 is specifically configured to: for every two test items in the plurality of test items, in response that a distance from a coordinate point formed by a correlation coefficient between the two test items in a test program and a correlation coefficient between the two test items in another test program to an origin of the difference analysis graph is greater than a second preset value, evaluate that the two test items have a significant difference in two different test programs.

In some embodiments, the first preset value is greater than the second preset value.

In some embodiments, the data obtaining module 710 is specifically configured to: determine, according to set parameters, a target product corresponding to the plurality of test programs; and

obtain test data of a preset test category of the target product from a test database, where

the preset test category include a plurality of test categories, and each test category corresponds to a plurality of test items.

In some embodiments, the data obtaining module 710 is further configured to merge the test data of the preset test category according to the set parameters to generate a merged data table.

In some embodiments, the set parameters include a test program identifier, a product identifier, a wafer identifier, a chip identifier, and a process step identifier.

In some embodiments, the system 700 for evaluating the test data further includes: an uploading module 770, configured to generate a difference report according to the evaluated difference of each test item in the two different test programs, and periodically upload the difference report.

In some embodiments, the test data is test data generated in a circuit probing stage.

It should be noted that, in the embodiments of the disclosure, the first drawing module 730 and the second drawing module 750 may execute corresponding drawing functions in parallel, and the first evaluation module 740 and the second evaluation module 760 may also execute corresponding evaluation functions in parallel.

The embodiments of the disclosure further provide a wafer test system. The wafer test system includes the above system for evaluating the test data.

Various constituent parts in the embodiments of the disclosure may be integrated in one processing unit, or various units may be physically present separately, or two or more units may be integrated in one unit. The above integrated units may be implemented in a form of hardware, or may be implemented in a form of a software functional module.

If the integrated unit is implemented in the form of a software functional module and is not sold or used as an independent product, the integrated unit may be stored in a computer-readable storage medium. Based on such understanding, the technical solutions of the embodiments of disclosure, in essence, or a part contributing to the prior art, or all or part of the technical solutions, may be embodied in a form of a software product, the computer software product is stored in a storage medium, and includes several instructions for enabling a computer device (which may be a personal computer, a server, or a network device, etc.) or a processor to perform all or part of the steps of the methods in the embodiments of the disclosure. The foregoing storage medium may be various media that may store program codes, such as a USB flash disk, a mobile hard disk, a Read-Only Memory (ROM), a Random Access Memory (RAM), a magnetic disk or an optical disk.

Therefore, the embodiments of the disclosure provide a storage medium having stored therein a computer program that when executed by at least one processor, implements the steps according the foregoing embodiments.

It should be noted that the computer storage medium illustrated in the disclosure may be a computer signal medium or a computer storage medium or a combination of the both. The computer storage medium may be—but is not limited to—an electric, magnetic, optical, electromagnetic, infrared, or semi-conductive system, apparatus, or component, or any combination thereof. More specific examples of the computer storage medium may include, but are not limited to: an electrical connection having one or more wires, a portable computer disk, a hard disk, an RAM, an ROM, an Erasable Programmable ROM (EPROM or a flash memory), an optical fiber, a portable Compact Disc ROM (CD-ROM), an optical storage device, a magnetic storage device, or any appropriate combination thereof. In the disclosure, the computer storage medium may be any tangible medium containing or storing programs which can be used by a command execution system, apparatus or device or in combination with a command execution system, apparatus or device. In the disclosure, the computer signal medium may include data signal in a base band or propagating as parts of a carrier, in which computer program codes are carried. The propagating data signal may take various forms, including but not limited to: an electromagnetic signal, an optical signal or any suitable combination thereof. The computer signal medium may also be any computer storage medium except for the computer storage medium. The computer storage medium is capable of transmitting, propagating or transferring programs for use by, or used in combination with, a command execution system, apparatus or device. The program codes contained on the computer storage medium may be transmitted with any suitable medium including but not limited to: wireless, wired, optical cable, RF medium etc., or any suitable combination thereof.

The flowcharts and block diagrams in the accompanying drawings illustrate architectures, functions and operations that may be implemented according to the systems, methods and computer program products of the various embodiments of the disclosure. In this regard, each of the blocks in the flowcharts or block diagrams may represent a module, a program segment, or a code portion, said module, program segment, or code portion including one or more executable instructions for implementing specified logic functions. It should also be noted that, in some alternative implementations, the functions denoted by the blocks may occur in a sequence different from the sequences illustrated in the drawings. For example, any two blocks presented in succession may be executed, substantially in parallel, or they may sometimes be in a reverse sequence, depending on the function involved. It should also be noted that each block in the block diagrams and/or flowcharts as well as a combination of blocks may be implemented using a dedicated hardware-based system executing specified functions or operations, or by a combination of a dedicated hardware and computer instructions.

It should be noted that although a plurality of modules or units of a device configured to perform actions are mentioned in the foregoing detailed description, such division is not mandatory. Actually, according to the implementations of the disclosure, the features and functions of two or more modules or units described above may be specified in one module or unit. Conversely, features and functions of one module or unit described above may be further divided into a plurality of modules or units to be specified.

The descriptions above are only specific implementations of the disclosure. However, the scope of protection of the disclosure is not limited thereto. Any modification or replacement easily made by persons skilled in the art within the technical scope disclosed by the disclosure shall fall within the scope of protection of the disclosure. Therefore, the scope of protection of the disclosure shall be subject to the scope of protection of the claims.

### INDUSTRIAL APPLICABILITY

In the technical solutions provided in the disclosure, a method for evaluating test data is provided. According to the method, a difference analysis graph is drawn for every two test programs in the plurality of test programs according to the correlation coefficient between each of the test items in different test programs, and a difference of each test item in two different test programs is evaluated according to the difference analysis graph. Thus, by means of the method for evaluating the test data provided in the disclosure, difference evaluation of each test item in different test programs is realized. An anomaly of a correlation difference between each of the test items caused by different test programs may be obtained according to the difference evaluation.

1. A method for evaluating test data, comprising:
obtaining test data of a plurality of test programs, each test program comprising a plurality of test items;
for each test program, calculating a correlation coefficient of each test item according to the test data;
drawing a difference analysis graph for every two test programs in the plurality of test programs according to correlation coefficients between each of the test items in different test programs, a horizontal axis and a longitudinal axis of the difference analysis graph respectively correspond to one test program; and
evaluating a difference of each test item in two different test programs according to the difference analysis graph.

2. The method of claim 1, wherein before the calculating the correlation coefficient of the each test item, the method further comprises:
drawing a box plot for each test item according to test data of each test item in different test programs; and
for each test item, removing abnormal test data by using the box plot.

3. The method of claim 2, wherein the calculating the correlation coefficient of the each test item according to the test data comprises:
calculating correlation coefficient between each of the test items according to test data after removing the abnormal test data.

4. The method of claim 2, wherein the each test program comprises the same test items.

5. The method of claim 4, further comprising:
evaluating the difference of the each test item in different test programs based on the box plot.

6. The method of claim 5, wherein the evaluating the difference of the each test item in different test programs comprises:
for the each test item, in response that a median in one of the plurality of test programs is greater than an upper quartile in another test program or less than a lower quartile in another test program, evaluating that the test item has a significance difference in different test programs.

7. The method of claim 1, wherein the calculating the correlation coefficient of the each test item comprises:
calculating the correlation coefficient between each of the test items by using a Pearson correlation coefficient calculation formula.

8. The method of claim 1, wherein for a first quadrant and a third quadrant of the difference analysis graph, the evaluating the difference of each test item in two different test programs comprises:
for every two test items in the plurality of test items, in response that a difference value between a correlation coefficient between the two test items in a test program and a correlation coefficient between the two test items in another test program is greater than a first preset value, evaluating that the two test items have a significant difference in two different test programs.

9. The method of claim 8, wherein for a second quadrant and a fourth quadrant of the difference analysis graph, the evaluating the difference of each test item in two different test programs further comprises:
for every two test items in the plurality of test items, in response that a distance from a coordinate point formed by a correlation coefficient between the two test items in a test program and a correlation coefficient between the two test items in another test program to an origin of the difference analysis graph is greater than a second preset value, evaluating that the two test items have a significant difference in two different test programs.

10. The method of claim 9, wherein
the first preset value is greater than the second preset value.

11. The method of claim 1, wherein the obtaining the test data of the plurality of test programs comprises:
determining, according to set parameters, a target product corresponding to the plurality of test programs; and
obtaining test data of a preset test category of the target product from a test database, wherein
the preset test category comprises a plurality of test categories, and each test category corresponds to a plurality of test items.

12. The method of claim 11, wherein before the calculating the correlation coefficient of the each test item according to the test data, the method further comprises:
merging the test data of the preset test category according to the set parameters to generate a merged data table.

13. The method of claim 11, wherein
the set parameters comprise a test program identifier, a product identifier, a wafer identifier, a chip identifier, and a process step identifier.

14. The method of claim 1, further comprising:
generating a difference report according to the evaluated difference of the each test item in the two different test programs; and
periodically uploading the difference report.

15. The method of claim 1, wherein
the test data is test data generated in a circuit probing stage.

16. A system for evaluating test data, comprising:
a processor; and
a memory for storing executable instructions executed by the processor;
wherein the processor is configured to:
obtain test data of a plurality of test programs, each test program comprising a plurality of test items;
for each test program, calculate a correlation coefficient of each test item according to the test data;
draw a difference analysis graph for every two test programs in the plurality of test programs according to correlation coefficients between each of the test items in different test programs, wherein a horizontal axis and a longitudinal axis of the difference analysis graph respectively correspond to one test program; and
evaluate a difference of each test item in two different test programs according to the difference analysis graph.

17. The system of claim 16, wherein before the calculating the correlation coefficient of the each test item, the processor is configured to:
drawing a box plot for each test item according to test data of each test item in different test programs; and
for each test item, removing abnormal test data by using the box plot.

18. The system of claim 17, wherein the calculating the correlation coefficient of the each test item according to the test data comprises:
calculating correlation coefficient between each of the test items according to test data after removing the abnormal test data.

19. The system of claim 17, wherein the each test program comprises the same test items, and the processor is further configured to evaluate the difference of the each test item in different test programs based on the box plot.

20. A non-transitory computer-readable storage medium having stored therein a computer program that when executed by a processor, implements a method for evaluating test data, wherein the method comprises:
obtaining test data of a plurality of test programs, each test program comprising a plurality of test items;
for each test program, calculating a correlation coefficient of each test item according to the test data;
drawing a difference analysis graph for every two test programs in the plurality of test programs according to correlation coefficients between each of the test items in different test programs, a horizontal axis and a longitudinal axis of the difference analysis graph respectively correspond to one test program; and
evaluating a difference of each test item in two different test programs according to the difference analysis graph.
